(19) United States
(12) Patent Application Publication
(10) Pub. No.: US 2025/0227869 A1
(43) Pub. Date: Jul. 10, 2025

(54) Server Information Handling System Mounting Width Conversion Bracket System

(71) Applicant: Dell Products L.P., Round Rock, TX (US)

(72) Inventors: Walter R. Carver, Round Rock, TX (US); Kevin Garrett, Austin, TX (US); Daniel Alvarado, Pflugerville, TX (US)

(21) Appl. No.: 18/408,639

(22) Filed: Jan. 10, 2024

(51) Int. Cl. H05K 7/14

(52) U.S. Cl. CPC H05K 7/1489

(57) ABSTRACT

A mounting width conversion bracket system. The mounting width conversion bracket system includes a left rail adapter assembly, the left rail adapter assembly having a width designed to fill a left portion of a gap between a wider width server rack and a standard width information handling system; and, a right rail adapter assembly, the right rail adapter assembly having a width designed to fill a right portion of the gap between the wider width server rack and the standard width information handling system.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for performing a wider server width, standard width information handling system mounting operation.

In one embodiment, the invention relates to a mounting width conversion bracket system for a server type information handling system, comprising: a left rail adapter assembly, the left rail adapter assembly having a width designed to fill a left portion of a gap between a wider width server rack and a standard width information handling system; and, a right rail adapter assembly, the right rail adapter assembly having a width designed to fill a right portion of the gap between the wider width server rack and the standard width information handling system.

In another embodiment, the invention relates to a server rack comprising: a wider width server rack, the wider width server rack including a left rack component and a right rack component; and, a mounting width conversion bracket system for a standard width server type information handling system, comprising: a left rail adapter assembly, the left rail adapter assembly having a width designed to fill a left portion of a gap between a wider width server rack and a standard width information handling system; and, a right rail adapter assembly, the right rail adapter assembly having a width designed to fill a right portion of the gap between the wider width server rack and the standard width information handling system.

In another embodiment, the invention relates to a rack mounting environment comprising: a standard width information handling system chassis; and, a mounting width conversion bracket system comprising: a left rail adapter assembly, the left rail adapter assembly having a width designed to fill a left portion of a gap between a wider width server rack and a standard width information handling system; and, a right rail adapter assembly, the right rail adapter assembly having a width designed to fill a right portion of the gap between the wider width server rack and the standard width information handling system.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a perspective view of a rack mounting environment.

FIG. 4 shows a perspective view of a mounting width conversion bracket system and cross hatching of an attached information handling system.

FIG. 5 shows a perspective view of a mounting width conversion bracket system.

FIGS. 6A and 6B, generally referred to as FIG. 6, show a right rail of a mounting width conversion bracket system.

FIGS. 7A and 7B, generally referred to as FIG. 7, show a left rail of a mounting width conversion system.

### DETAILED DESCRIPTION

Various aspects of the disclosure include an appreciation that server racks can be configured as standard width server racks while other server racks can be configured as wider width server racks. For example, it is known to provide standard width server racks with a front panel width of substantially (i.e., +/−10%) 19 inches and a rack opening width of substantially (i.e., +/−10%) 17.75 inches. Various aspects of the present disclosure include an appreciation that standard width server racks are configured to hold standard width server type information handling systems. Various aspects of the present disclosure include an appreciation that certain standard width server type information handling systems can have a chassis width of substantially (i.e., +/−10%) 17.09 inches which fit within a rack opening of substantially (i.e., +/−10%) 17.75 inches.

Various aspects of the present disclosure include an appreciation that certain wider width server racks can conform to rack standards such as the open compute project (OCP) OpenRack standard. Various aspects of the present disclosure include an appreciation that a significant difference between the current 19″ rack standard and OpenRack standard, is that the OpenRack standard can support IT devices up to 23-inches wide. Various aspects of the present disclosure include an appreciation that the OpenRack standard can support and has a built-in DC busbar to provide power to the IT devices mounted within the rack.

Accordingly, it would be desirable to provide a mounting solution which can adapt a standard 19″ server to be mounted within a rack conforming to the OpenRack standard.

A system and method are disclosed for performing a wider server width, standard width information handling system mounting operation. In certain embodiments, the system and method make use of a mounting width conversion bracket system. In certain embodiments, the mounting width conversion bracket system is configured to attach a standard width information handing system to mounting features which conform to a wider width rack standard. In certain embodiments, the mounting width conversion bracket system includes integrated slide rails. In certain embodiments, the integrated slide rails include wider width mounting features that mate with inner rails which are attached to the server type information handling system. In certain embodiments, the mounting width conversion bracket system is designed to fill the gap between a wider width server rack and a standard width information handling system. In certain embodiments, the mounting width conversion bracket system is designed to fill the gap between a 23-inch OpenRack rack and 19″ wide information handling system.

In certain embodiments, the mounting width conversion bracket system includes a power connector bracket to facilitate connection of the information handling system to a power busbar. In certain embodiments, the power connector bracket is physically coupled between the two inner rails attached to the server type information handling system. In certain embodiments, the power connector bracket includes a connector that plugs into the busbar. In certain embodiments, the inner rails and power connector bracket move in tandem as the server information handing system is inserted and removed from the wider width server rack. In certain embodiments, the mounting width conversion bracket system supports blind plug into the busbar.

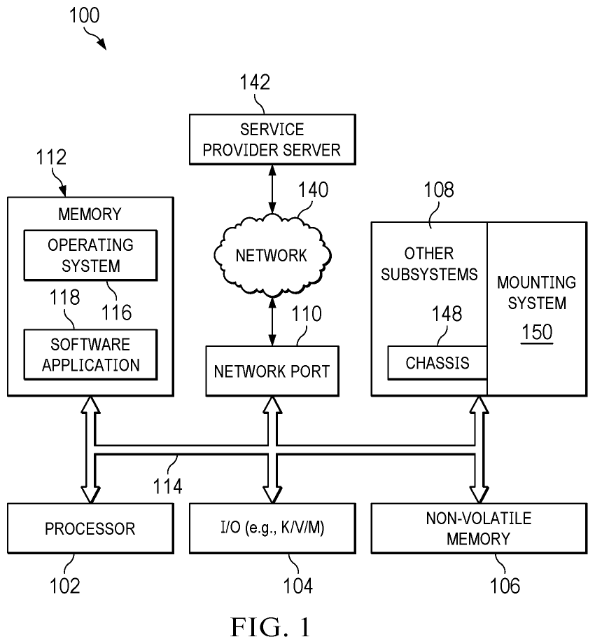

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, the other sub systems 108 include a chassis 148. In certain embodiments, some or all of the other components of the information handling system 100 are contained within the chassis 148. In certain embodiments, the chassis interacts with a mounting system 150. In certain embodiments, the mounting system 150 physically attaches the chassis 148 to a server rack. In certain embodiments, the chassis 148 includes a standard width chassis. In certain embodiments, the mounting system 150 includes a mounting width conversion bracket system.

In certain embodiments, the mounting width conversion bracket system is configured to attach a standard width information handing system to mounting features which conform to a wider width rack standard. In certain embodiments, the mounting width conversion bracket system includes integrated slide rails. In certain embodiments, the integrated slide rails include wider width mounting features that mate with inner rails which are attached to the server type information handling system. In certain embodiments, the mounting width conversion bracket system is designed to fill the gap between a wider width server rack and a standard width information handling system. In certain embodiments, the mounting width conversion bracket system is designed to fill the gap between a 23-inch OpenRack rack and 19″ wide information handling system.

In certain embodiments, the mounting width conversion bracket system includes a power connector bracket to facilitate connection of the information handling system to a power busbar. In certain embodiments, the power connector bracket is physically coupled between the two inner rails attached to the server type information handling system. In certain embodiments, the power connector bracket includes a connector that plugs into the busbar. In certain embodiments, the inner rails and power connector bracket move in tandem as the server information handling system is inserted and removed from the wider width server rack. In certain embodiments, the mounting width conversion bracket system supports blind plug into the busbar.

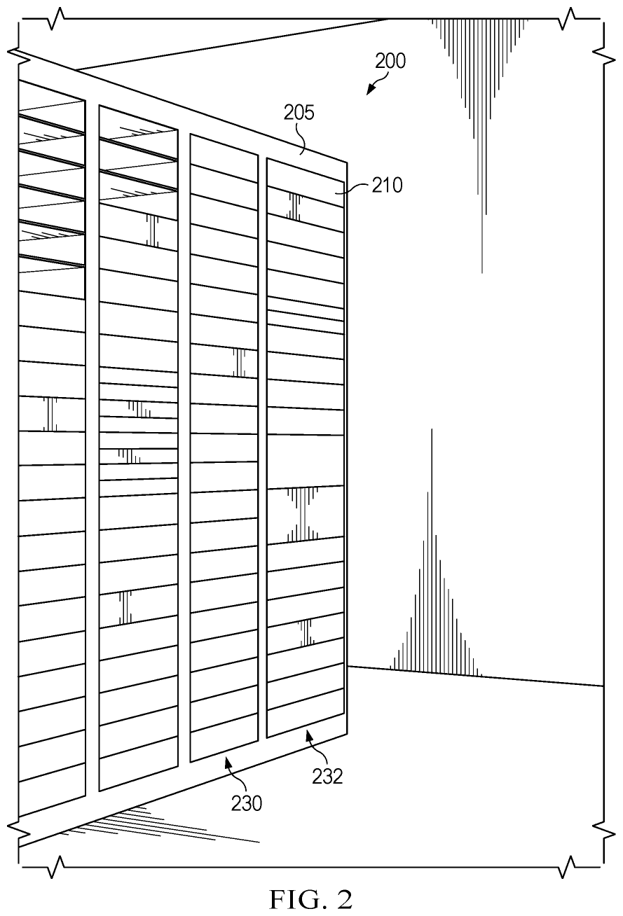

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems, and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems 210 correspond to information handling systems 100. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1U rack unit, a 2U rack unit and a 4U rack unit. In general, a 1U rack unit is substantially (i.e., +/−20%) 1.75″ high, a 2U rack unit is substantially (i.e., +/−20%) 3.5″ high, and a 4U rack height is substantially (i.e., +/−20%) 7.0″ high. Alternately, with rack units which conform to the OpenRack standard, a 1U rack unit is substantially (i.e., +/−20%) 1.89″ high, a 2U rack unit is substantially (i.e., +/−20%) 3.78″ high, and a 4U rack height is substantially (i.e., +/−20%) 7.56″ high.

In certain embodiments, one or more of the plurality of racks are configured to include a standard width portion 230 to hold standard width server type information handling systems. In certain embodiments, one or more of the plurality of racks are configured as wider width server racks 232. In certain embodiments, one or more of the wider width server racks conform to the OpenRack standard. In certain embodiments the standard width server type information handling systems have a front panel width of substantially (i.e., +/−20%) 19 inches wide. In certain embodiments, the wider width server type information handling systems have a front panel width of substantially (i.e., +/−20%) 23-inches wide.

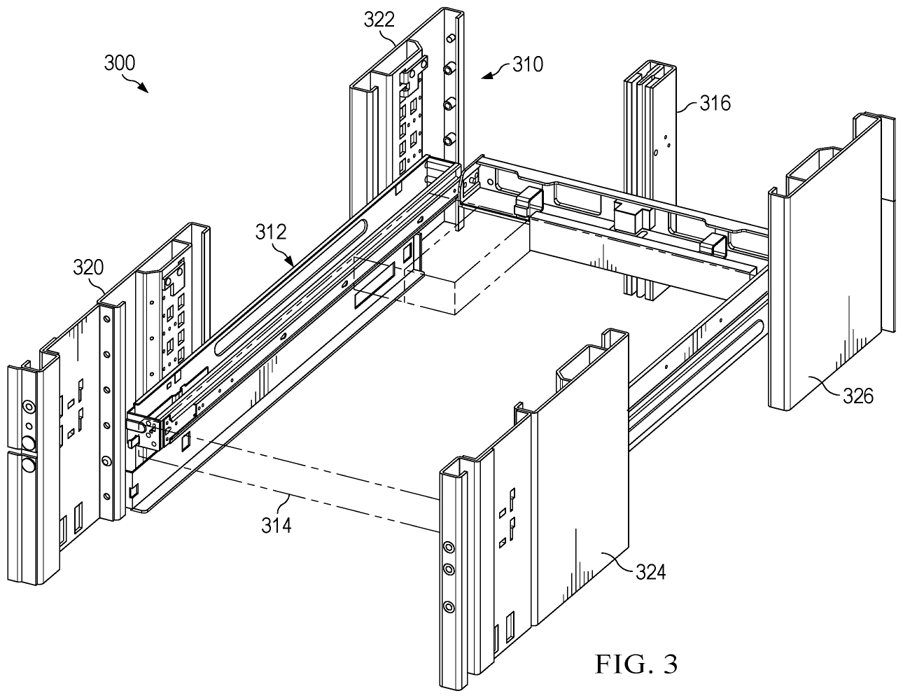

FIG. 3 shows a perspective view of a rack mounting environment 300. In certain embodiments, the rack mounting environment 300 includes a wider width rack 310, a mounting width conversion bracket system 312, a standard width server type information handling system 314, a busbar 316, or a combination thereof. In certain embodiments, the mounting width conversion bracket system 312 corresponds to mounting system 150. In certain embodiments, the information handling system 314 corresponds to information handling system 100. As used herein, a wider width server rack broadly refers to a server rack having a mounting width greater than the mounting width of a standard mounting width server rack. In certain embodiments, a wider width server rack conforms to a rack standard such as the open compute project (OCP) OpenRack standard. In certain embodiments, a wider width server rack has a mounting width of substantially (i.e., +/−20%) 23-inches wide. As used herein, a standard width server type information handling system broadly refers to an information handling system having a width designed to mount within a standard width server rack. In certain embodiments, the width of a standard width server type information handing system is substantially (i.e., +/−20%) 19 inches wide.

In certain embodiments, the wider width rack 310 includes a left front rack component 320, a left rear rack component 322, a right front rack component 324 and a right rear rack component 326. In certain embodiments, a left portion of the mounting width conversion bracket system 312 mounts to the left front rack component 320, the left rear rack component 322, or a combination thereof. In certain embodiments, a right portion of the mounting width conversion bracket system 312 mounts to the right front rack component 324, the right rear rack component 326, or a combination thereof.

In certain embodiments, the mounting width conversion bracket system 312 is configured to attach a standard width information handing system to mounting features which conform to a wider width rack standard. In certain embodiments, the mounting width conversion bracket system 312 includes integrated slide rails. In certain embodiments, the integrated slide rails include wider width mounting features that mate with inner rails which are attached to the server type information handling system. In certain embodiments, the mounting width conversion bracket system 312 is designed to fill the gap between a wider width server rack and a standard width information handling system. In certain embodiments, the mounting width conversion bracket system 312 is designed to fill the gap between a 23-inch OpenRack rack and 19″ wide information handling system.

In certain embodiments, the mounting width conversion bracket system 312 includes a power connector bracket to facilitate connection of the information handling system to a power busbar 316. In certain embodiments, the power connector bracket is physically coupled between the two inner rails attached to the server type information handling system. In certain embodiments, the power connector bracket includes a connector that plugs into the busbar 316. In certain embodiments, the inner rails and power connector bracket move in tandem as the server information handing system is inserted and removed from the wider width server rack. In certain embodiments, the mounting width conversion bracket system supports blind plug into the busbar.

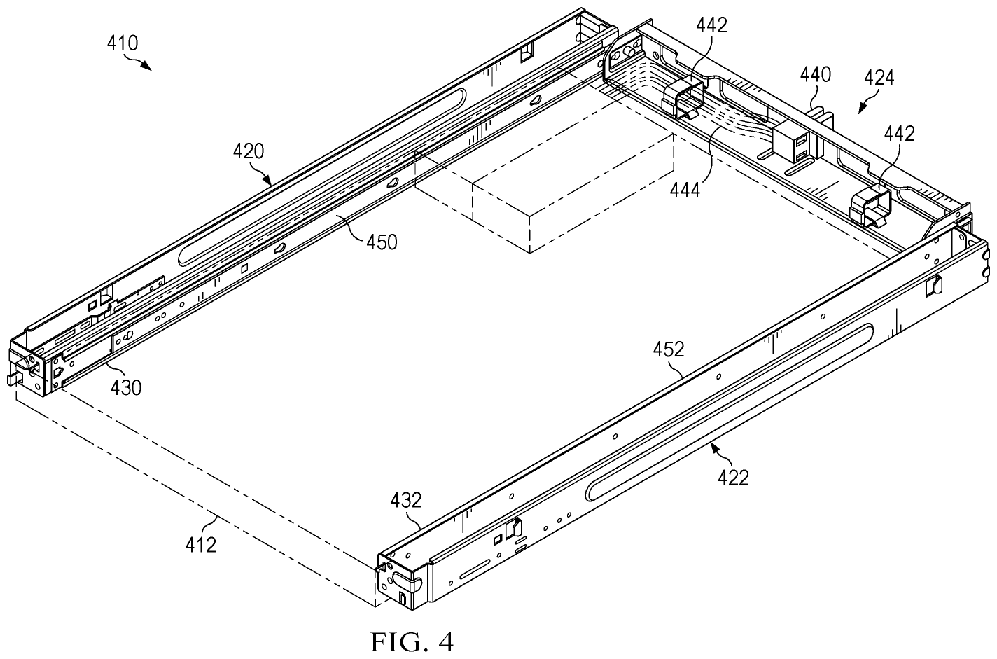

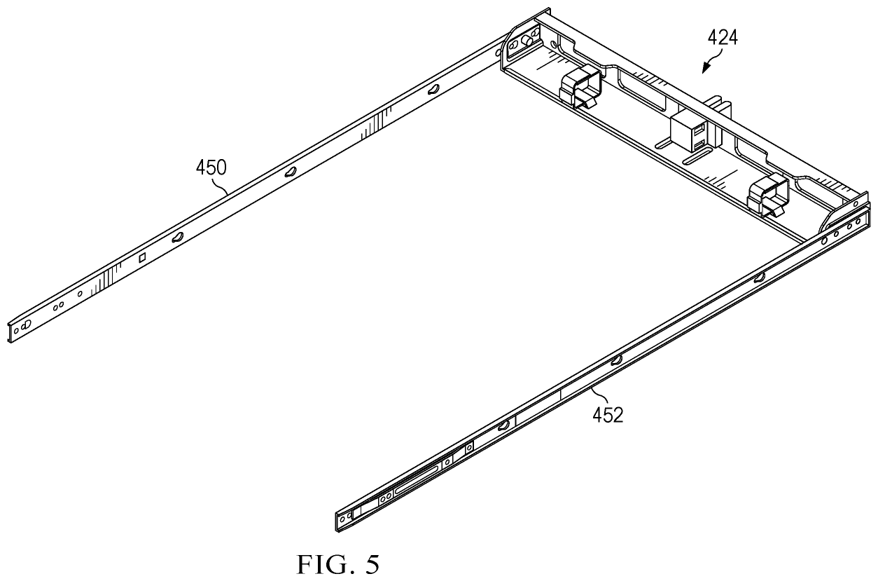

FIG. 4 shows a perspective view of a mounting width conversion bracket system 410 and cross hatching of an attached information handling system 412. FIG. 5 shows a perspective view of a mounting width conversion bracket system. In certain embodiments, the mounting width conversion bracket system 410 corresponds to mounting system 150. In certain embodiments, the information handling system 412 corresponds to information handling system 100.

In certain embodiments, the mounting width conversion bracket system 410 is configured to attach a standard width information handing system to mounting features which conform to a wider width rack standard. In certain embodiments, the mounting width conversion bracket system 410 includes a left rail adapter assembly 420, a right rail adapter assembly 422, a power connector bracket assembly 424, or a combination thereof. In certain embodiments, the left rail adapter assembly 420, the right rail adapter assembly 422, or a combination thereof each include wider width mounting features that mate with inner rails which are attached to the server type information handling system. In certain embodiments, the rail adapter assemblies 420, 422 are designed to fill the gap between a wider width server rack and a standard width information handling system. In certain embodiments, the rail adapter assemblies 420, 422 are designed to fill the gap between a 23-inch OpenRack rack and 19″ wide information handling system.

In certain embodiments, the left rail adapter assembly 420 includes a left integrated slide rail 430. In certain embodiments, the right rail adapter assembly 422 includes a right integrated slide rail 432. In certain embodiments, the left integrated slide rail 430, the right integrated slide rail 432, or a combination thereof, each include mounting features that mate with slide rails 450, 452 which are attached to respective sides of the server type information handling system.

In certain embodiments, the power connector bracket assembly 424 facilitates connection of a standard width information handling system to a server rack power source such as a server rack power busbar. In certain embodiments, the power connector bracket assembly 424 is physically coupled between slide rails 450, 452 attached to the server type information handling system. In certain embodiments, the power connector bracket assembly 424 is physically coupled between the left rail adapter assembly 420 and the right rail adapter assembly 422. In certain embodiments, the power connector bracket assembly 424 includes a connector 440 that plugs into the busbar. In certain embodiments, the power connector bracket assembly 424 includes one or more cable guides 442. In certain embodiments, the one or more cable guides 442 route cables from the connector to a power receiver of an attached information handling system.

In certain embodiments, the inner rails 450, 452 attached to the server type information handling system and power connector bracket assembly 424 move in tandem as the server information handing system 412 is inserted and removed from the wider width server rack. In certain embodiments, the mounting width conversion bracket system supports blind plug into the busbar.

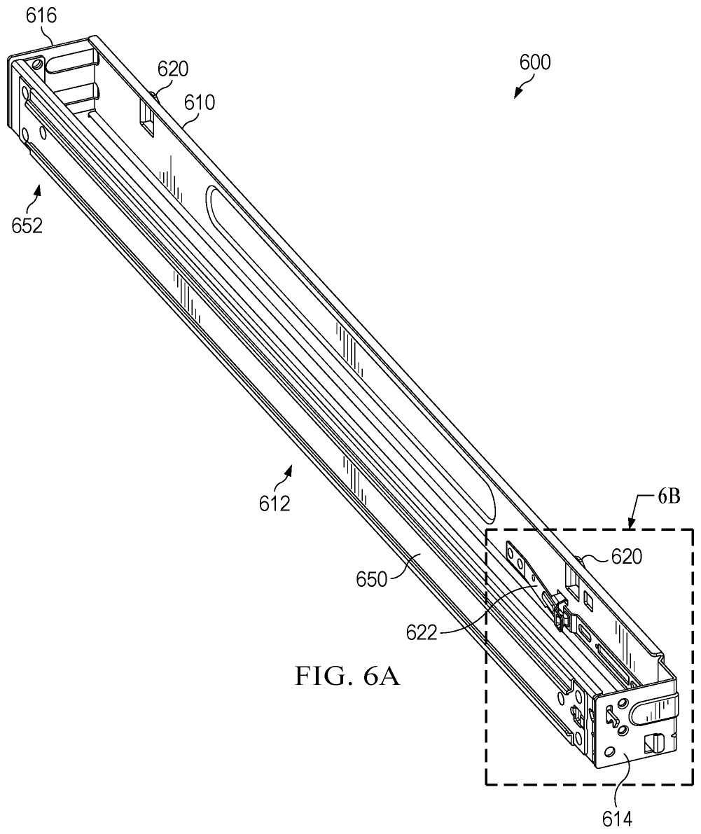

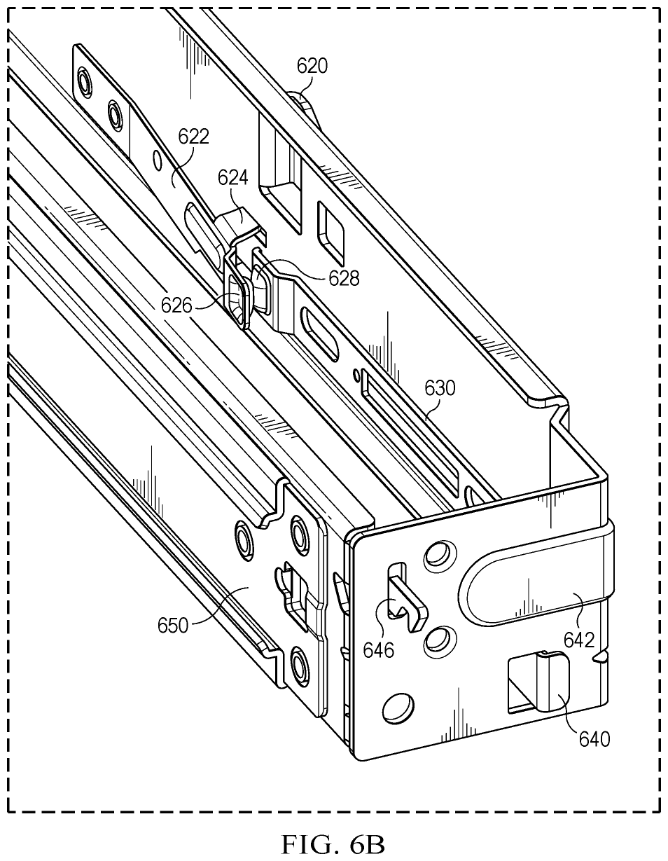

FIGS. 6A and 6B, generally referred to as FIG. 6, show a right rail adapter assembly 600 of a mounting width conversion bracket system. In certain embodiments, the right rail adapter assembly 600 corresponds to right rail adapter assembly 422. In certain embodiments, the right rail adapter assembly 600 includes wider width mounting features that mate with inner rails which are attached to a right side of a chassis of a server type information handling system. In certain embodiments, the right rail adapter assembly 600 has a width which is designed to fill a portion of the gap between a wider width server rack and a standard width information handling system. In certain embodiments, the right rail adapter assembly 600 has a width which is designed to fill a portion of the gap between a 23-inch OpenRack rack and 19″ wide information handling system.

In certain embodiments, the right rail adapter assembly 600 includes a right rail outside wall component 610, a right rail inside wall component 612, a right rail front wall component 614, a right rail rear wall component 616, or a combination thereof. In certain embodiments, the right rail outside wall component 610 and the right rail inside wall component 612 extend substantially (i.e., +/−10%) parallel with each other. In certain embodiments, the right rail front wall component 614 and the right rail rear wall component 616 extend substantially (i.e., +/−10%) parallel with each other.

In certain embodiments, the right rail front wall component 614 and the right rail rear wall component 616 extend substantially (i.e., +/−10%) perpendicular to the right rail outside wall component 610 and the right rail inside wall component 612. In certain embodiments, the right rail front wall component 614 and the right rail rear wall component 616 extend from the right rail outside wall component 610 to the right rail inside wall component 612 to provide the bracket assembly with a width designed to fill a portion of the gap between a wider width server rack and a standard width information handling system. In certain embodiments, the right rail front wall component 614 and the right rail rear wall component 616 extend substantially (i.e., +/−20%) 2 inches from the right rail outside wall component 610 to the right rail inside wall component 612 to fill a portion of the gap between a wider width server rack and a standard width information handling system. In certain embodiments, the right rail front wall component 614 and the right rail rear wall component 616 extend from the right rail outside wall component 610 to the right rail inside wall component 612 designed to fill a portion of the gap between a 23-inch OpenRack rack and 19″ wide information handling system.

In certain embodiments, the right rail outside wall component 610 includes one or more mounting hook features 620. In certain embodiments, the one or more mounting hook features 620 interface with apertures defined by a rack components of a wider width rack (see e.g., rack components right front rack component 324 and right rear rack component 326).

In certain embodiments, the right rail outside wall component 610 includes a rack interface latch 622. In certain embodiments, the rack interface latch 622 includes a latch projection 624 which extends substantially perpendicularly inward from the right rail outside wall component 610 towards a rack component of a wider width rack. In certain embodiments, the latch projection 624 interfaces with an aperture defined by the rack component of the wider width rack to hold an information handling system attached to the right rail adapter assembly 600 in a closed (i.e., inserted) orientation within the wider width rack. In certain embodiments, the rack interface latch 622 includes a latch projection 626 which interacts with a projection 628 extending inwardly from an inside wall of the right rail outside wall component 610. In certain embodiments, when the latch projection 626 interacts with the projection 628 extending inwardly from an inside wall of the right rail outside wall component 610, the rack interface latch 622 is inwardly extended away from the inside wall of the right rail outside wall component 610. In certain embodiments, the inward extension enables an information handling system attached to the right rail adapter assembly 600 to be slid from an inserted orientation in the rack to an extended orientation in the rack. In certain embodiments, the rack interface latch 622 is released via a latch release component 630. In certain embodiments, the projection 628 is integrated with the latch release component 630.

In certain embodiments, the right rail front wall component 614 includes one or more server attachment features. In certain embodiments, the one or more server attachment features include a slam latch 640. In certain embodiments, the one or more server attachment features include a server guide projection 642. In certain embodiments, a tab 644 extending from a front portion of the latch release 630 functions as a server attachment feature.

In certain embodiments, the right rail inside wall component 616 includes a right side integrated slide rail 650. In certain embodiments, the right integrated slide rail 650 includes mounting features that mate with a right slide rail which is attached to a right side of the server type information handling system. In certain embodiments, the right integrated slide rail 650 defines a plurality of apertures 652 at a rear portion of the right integrated slide rail. In certain embodiments, the plurality of apertures 652 enable fasteners to attach a power connector bracket assembly to be attached to the right integrated slide rail 650.

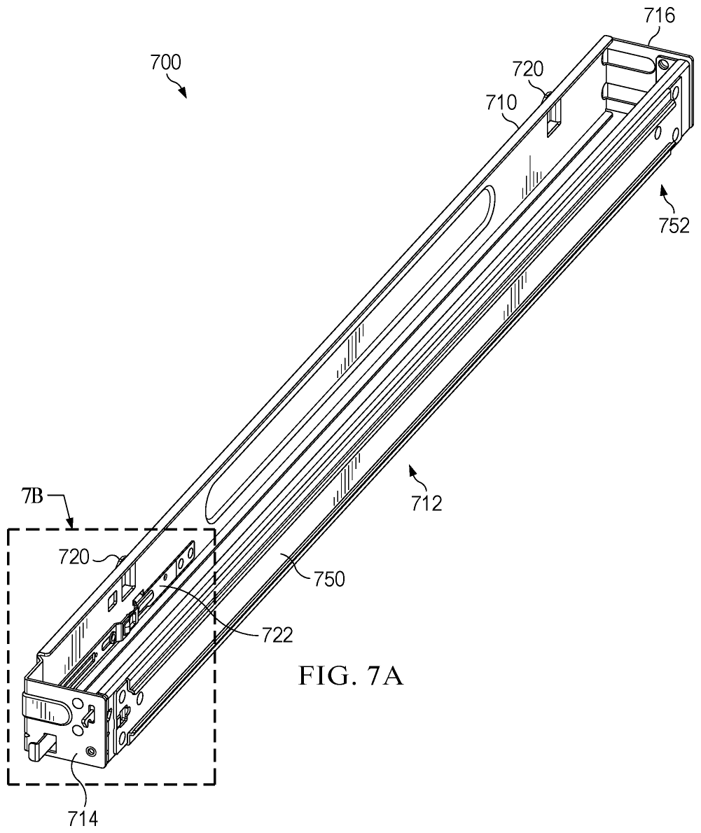

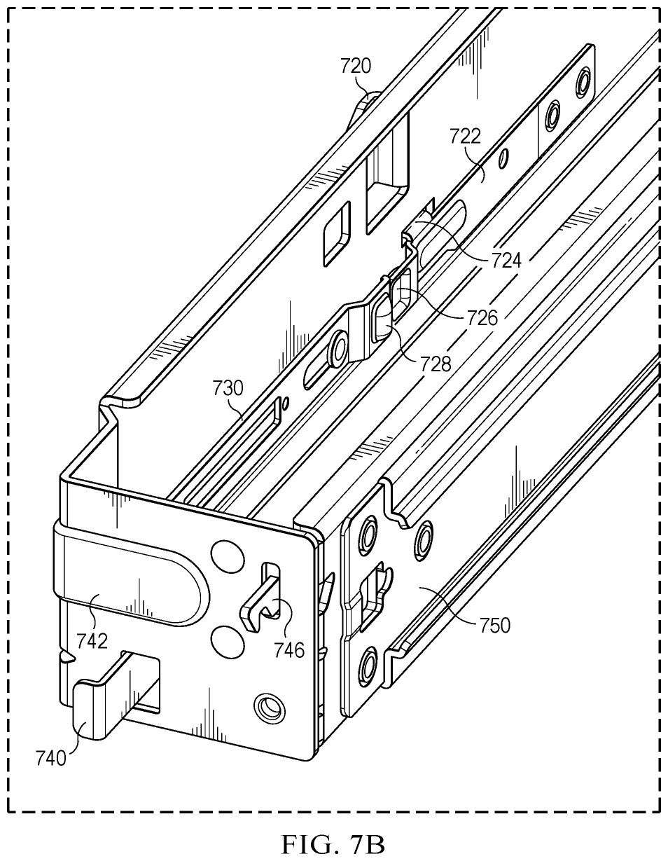

FIGS. 7A and 7B, generally referred to as FIG. 7, show a left rail adapter assembly 700 of a mounting width conversion system. In certain embodiments, the left rail adapter assembly 700 corresponds to left rail adapter assembly 420. In certain embodiments, the left rail adapter assembly 700 includes wider width mounting features that mate with inner rails which are attached to a left side of a chassis of a server type information handling system. In certain embodiments, the left rail adapter assembly 700 has a width which is designed to fill a portion of the gap between a wider width server rack and a standard width information handling system. In certain embodiments, the left rail adapter assembly 700 has a width which is designed to fill a portion of the gap between a 23-inch OpenRack rack and 19″ wide information handling system.

In certain embodiments, the left rail adapter assembly 700 includes a left rail outside wall component 710, a left rail inside wall component 712, a left rail front wall component 714, a left rail rear wall component 716, or a combination thereof. In certain embodiments, the left rail outside wall component 710 and the left rail inside wall component 712 extend substantially (i.e., +/−10%) parallel with each other. In certain embodiments, the left rail front wall component 714 and the left rail rear wall component 716 extend substantially (i.e., +/−10%) parallel with each other.

In certain embodiments, the left rail front wall component 714 and the left rail rear wall component 716 extend substantially (i.e., +/−10%) perpendicular to the left rail outside wall component 710 and the left rail inside wall component 712. In certain embodiments, the left rail front wall component 714 and the left rail rear wall component 716 extend from the left rail outside wall component 710 to the left rail inside wall component 712 to provide the bracket assembly with a width designed to fill a portion of the gap between a wider width server rack and a standard width information handling system. In certain embodiments, the left rail front wall component 714 and the left rail rear wall component 716 extend substantially (i.e., +/−20%) 2 inches from the left rail outside wall component 710 to the left rail inside wall component 712 to fill a portion of the gap between a wider width server rack and a standard width information handling system. In certain embodiments, the left rail front wall component 714 and the left rail rear wall component 716 extend from the left rail outside wall component 710 to the left rail inside wall component 712 designed to fill a portion of the gap between a 23-inch OpenRack rack and 19″ wide information handling system.

In certain embodiments, the left rail outside wall component 710 includes one or more mounting hook features 720. In certain embodiments, the one or more mounting hook features 720 interface with apertures defined by a rack components of a wider width rack (see e.g., rack components left front rack component 324 and left rear rack component 326).

In certain embodiments, the left rail outside wall component 710 includes a rack interface latch 722. In certain embodiments, the rack interface latch 722 includes a latch projection 724 which extends substantially perpendicularly inward from the left rail outside wall component 710 towards a rack component of a wider width rack. In certain embodiments, the latch projection 724 interfaces with an aperture defined by the rack component of the wider width rack to hold an information handling system attached to the left rail adapter assembly 700 in a closed (i.e., inserted) orientation within the wider width rack. In certain embodiments, the rack interface latch 722 includes a latch projection 726 which interacts with a projection 728 extending inwardly from an inside wall of the left rail outside wall component 710. In certain embodiments, when the latch projection 726 interacts with the projection 728 extending inwardly from an inside wall of the left rail outside wall component 710, the rack interface latch 722 is inwardly extended away from the inside wall of the left rail outside wall component 710. In certain embodiments, the inward extension enables an information handling system attached to the left rail adapter assembly 700 to be slid from an inserted orientation in the rack to an extended orientation in the rack. In certain embodiments, the rack interface latch 722 is released via a latch release component 730. In certain embodiments, the projection 728 is integrated with the latch release component 730.

In certain embodiments, the left rail front wall component 714 includes one or more server attachment features. In certain embodiments, the one or more server attachment features include a slam latch 740. In certain embodiments, the one or more server attachment features include a server guide projection 742. In certain embodiments, a tab 744 extending from a front portion of the latch release 730 functions as a server attachment feature.

In certain embodiments, the left rail inside wall component 712 includes a left side integrated slide rail 750. In certain embodiments, the left integrated slide rail 750 includes mounting features that mate with a left slide rail which is attached to a left side of the server type information handling system. In certain embodiments, the left integrated slide rail 750 defines a plurality of apertures 752 at a rear portion of the left integrated slide rail. In certain embodiments, the plurality of apertures 752 enable fasteners to attach a power connector bracket assembly to be attached to the left integrated slide rail 750.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. A mounting width conversion bracket system for a server type information handling system, comprising:
a left rail adapter assembly, the left rail adapter assembly having a width designed to fill a left portion of a gap between a wider width server rack and a standard width information handling system; and,
a right rail adapter assembly, the right rail adapter assembly having a width designed to fill a right portion of the gap between the wider width server rack and the standard width information handling system.

2. The mounting width conversion bracket system of claim 1, wherein:
the left rail adapter assembly includes a left rail front wall component and a left rail rear wall component, the left rail front wall component and the left rail rear wall component providing the left rail bracket assembly with the width designed to fill the portion of the gap between the wider width server rack and the standard width information handling system; and,
the right rail adapter assembly includes a right rail front wall component and a right rail rear wall component, the right rail front wall component and the let rail rear wall component providing the right rail bracket assembly with the width designed to fill the portion of the gap between the wider width server rack and the standard width information handling system.

3. The mounting width conversion bracket system of claim 2, wherein:
the left rail front wall component comprises a left bracket assembly server attachment feature; and,
the right rail front wall component comprises a right bracket assembly server attachment feature.

4. The mounting width conversion bracket system of claim 1, wherein:
the left rail adapter assembly includes a left rail outside wall component and a left rail inside wall component, the left rail outside wall component and the left rail inside wall component extending substantially parallel; and,
the right rail adapter assembly includes a right rail outside wall component and a right rail inside wall component, the right rail outside wall component and the right rail inside wall component extending substantially parallel.

5. The mounting width conversion bracket system of claim 1, further comprising:
a power connector bracket assembly extending between the left rail adapter assembly and the right rail adapter assembly, the power bracket assembly facilitating connection of the information handling system with a server rack power source.

6. The mounting width conversion bracket system of claim 5, wherein:
the power connector bracket assembly includes a busbar clip.

7. A server rack comprising:
a wider width server rack, the wider width server rack including a left rack component and a right rack component; and,
a mounting width conversion bracket system for a standard width server type information handling system, comprising:
a left rail adapter assembly, the left rail adapter assembly having a width designed to fill a left portion of a gap between the wider width server rack and the standard width server type information handling system; and,
a right rail adapter assembly, the right rail adapter assembly having a width designed to fill a right portion of the gap between the wider width server rack and the standard width server type information handling system.

8. The server rack of claim 7, wherein:
the left rail adapter assembly includes a left rail front wall component and a left rail rear wall component, the left rail front wall component and the left rail rear wall component providing the left rail bracket assembly with the width designed to fill the portion of the gap between the wider width server rack and the standard width information handling system; and,
the right rail adapter assembly includes a right rail front wall component and a right rail rear wall component, the right rail front wall component and the let rail rear wall component providing the right rail bracket assembly with the width designed to fill the portion of the gap between the wider width server rack and the standard width information handling system.

9. The server rack of claim 8, wherein:
the left rail front wall component comprises a left bracket assembly server attachment feature; and,
the right rail front wall component comprises a right bracket assembly server attachment feature.

10. The server rack of claim 7, wherein:
the left rail adapter assembly includes a left rail outside wall component and a left rail inside wall component, the left rail outside wall component and the left rail inside wall component extending substantially parallel; and,
the right rail adapter assembly includes a right rail outside wall component and a right rail inside wall component, the right rail outside wall component and the right rail inside wall component extending substantially parallel.

11. The server rack of claim 7, wherein the mounting width conversion bracket system further comprises:
a power connector bracket assembly extending between the left rail adapter assembly and the right rail adapter assembly, the power bracket assembly facilitating connection of the information handling system with a server rack power source.

12. The server rack of claim 11, wherein:
the power connector bracket assembly includes a busbar clip.

13. A rack mounting environment comprising:
a standard width information handling system chassis; and,
a mounting width conversion bracket system comprising:
a left rail adapter assembly, the left rail adapter assembly having a width designed to fill a left portion of a gap between a wider width server rack and the standard width server type information handling system; and,
a right rail adapter assembly, the right rail adapter assembly having a width designed to fill a right portion of the gap between the wider width server rack and the standard width server type information handling system.

14. The rack mounting environment of claim 13, wherein:
the left rail adapter assembly includes a left rail front wall component and a left rail rear wall component, the left rail front wall component and the left rail rear wall component providing the left rail bracket assembly with the width designed to fill the portion of the gap between the wider width server rack and the standard width information handling system; and,
the right rail adapter assembly includes a right rail front wall component and a right rail rear wall component, the right rail front wall component and the let rail rear wall component providing the right rail bracket assembly with the width designed to fill the portion of the gap between the wider width server rack and the standard width information handling system.

15. The rack mounting environment of claim 14, wherein:
the left rail front wall component comprises a left bracket assembly server attachment feature; and,
the right rail front wall component comprises a right bracket assembly server attachment feature.

16. The rack mounting environment of claim 14, wherein:
the left rail adapter assembly includes a left rail outside wall component and a left rail inside wall component, the left rail outside wall component and the left rail inside wall component extending substantially parallel; and,
the right rail adapter assembly includes a right rail outside wall component and a right rail inside wall component, the right rail outside wall component and the right rail inside wall component extending substantially parallel.

17. The rack mounting environment of claim 13, wherein the mounting width conversion bracket system further comprises:
a power connector bracket assembly extending between the left rail adapter assembly and the right rail adapter assembly, the power bracket assembly facilitating connection of the information handling system with a server rack power source.

18. The rack mounting environment of claim 17, wherein:
the power connector bracket assembly includes a busbar clip.
